(19) United States
(12) Patent Application Publication
(10) Pub. No.: US 2022/0220604 A1
(43) Pub. Date: Jul. 14, 2022

(54) LOW-PRESSURE COATING SYSTEM AND METHOD FOR COATING SEPARATED POWDERS OR FIBRES BY MEANS OF PHYSICAL OR CHEMICAL VAPOUR PHASE DEPOSITION

(71) Applicant: Fraunhofer-Gesellschaft Zur Förderung Der Angewandten Forschung E.V., München (DE)

(72) Inventors: Nils MAINUSCH, Göttingen (DE); Daniel SCHOLZ, Hildesheim (DE); Wolfgang VIÖL, Hildesheim (DE); Oliver KAPPERTZ, Hildesheim (DE); Tim TIELEBÖRGER, Hildesheim (DE); Stefan ZEBROWSKI, Hildesheim (DE)

(73) Assignee: FRAUNHOFER-GESELLSCHAFT ZUR FÖRDERUNG DER ANGEWANDTEN FORSCHUNG E.V., München (DE)

(21) Appl. No.: 17/709,000

(22) Filed: Mar. 30, 2022

Related U.S. Application Data
(63) Continuation of application No. PCT/EP2020/077321, filed on Sep. 30, 2020.

(30) Foreign Application Priority Data
Sep. 30, 2019 (DE) 10 2019 215 044.6

(51) Int. Cl. C23C 14/34; B22F 1/17; B22F 1/18; B22F 1/16; C23C 16/00

(52) U.S. Cl. CPC C23C 14/34; B22F 1/17; C23C 16/00; B22F 1/16; B22F 1/18

(57) ABSTRACT

The invention relates to a low-pressure coating system and a method for coating particle or fibre collectives by means of physical or chemical vapour phase deposition. A deagglomeration unit is used, by means of which the particle or fibre collective is separated and then coated. These particles are used for example as active material for batteries and capacitors and as 3D printing powder or colour pigments. The fibres are used for example for textiles, membranes, filters or composite materials.

### CROSS-REFERENCE TO RELATED APPLICATIONS

This patent application is a continuation of International Application No. PCT/EP2020/077321, filed on Sep. 30, 2020, which claims the benefit of German Patent Application No. 10 2019 215 044.6, filed Sep. 30, 2019, the disclosures of which are incorporated herein by reference in their entireties for all purposes.

### BACKGROUND OF THE INVENTION

The invention relates to a low-pressure coating system and a method for coating particle or fiber collectives by means of physical or chemical vapor deposition. A deagglomeration unit, through which the particle or fiber collectives are separated and then coated, is used here. Said particles are used, for example, as active material for batteries and capacitors and as 3D printing powder or color pigments. The fibers are used, for example, for textiles, membranes, filters or composite materials.

There are a large number of industrial applications in which powder materials, in particular collectives of fine particles (diameter from 10 μm to 100 μm) or ultrafine particles (diameter <10 μm), are used as a starting material and processed further or constitute an end product. Properties which directly influence further processing, such as chemical resistance, electrical or thermal conductivity, optical behavior, dispersibility and flow behavior, are also determined by the nature of the particle surface. In some cases, a target property, for example, a catalytic function, can only be efficiently adjusted by surface treatment. Functionalization of particle surfaces can therefore have a significant influence on final product quality. Analogously to powder materials, starting materials and product optimizations, which result from a modification of the fiber surface, are also known in the case of fibers. This applies, for example, to fiber composites, in which the cohesion of the matrix depends on the quality of the bond between the fibers and further composite components, which in turn determines the nature of the fiber surfaces.

Thin coatings (usually <<1 μm) of particles and fibers are presented in the prior art, which particles and fibers are produced by means of wet-chemical methods for certain metals or by means of pyrolysis for carbon. The attractiveness of using physical or chemical vapor deposition (PVD, CVD) is based on the fact that various types of carbon, almost all metals and inorganic materials and—with the help of reactive process management—also oxides, nitrides or carbides, can be deposited in a highly clean environment by means of a very controlled layer formation rate. In addition, composite coatings, graded coatings and multi-layer coating systems can be produced efficiently.

A feature of sputtering, however, is that the layer-forming species drift in a directed manner; the particle surfaces to be coated must in principle be uncovered and directly accessible. Particle or fiber overlays or accumulations on system walls lead to coverings and shadows that impair layer formation. This requirement must be met in a comparable way for all variants of physical or chemical vapor deposition.

For this reason, it is imperative to separate particle or fiber collectives in the coating process. Furthermore, the separated particles or fibers must be fluidized and the fluid exposed to the coating species. This must also be made possible with a controllable dwell time of the fluid in the structure of the coating species, without the occurrence of re-agglomerations or adhesion of the particles or fibers to the walls.

These requirements (separation, fluidization and exposure of the fluid to the coating species that can be controlled over time) result in the technical problem that the cohesive and adhesive holding and frictional forces of finely divided particle or fiber collectives have to be overcome or bonds have to be broken under the working conditions for PVD or CVD (low-pressure environment, that is, no aids that can be introduced such as dispersing liquid phases or sufficiently impulse-transmitting gas molecules). The forces include surface and field forces (van der Waals forces, electrostatic and magnetic forces), material bridges (liquid and solid state bridges), hydrogen bonds and form-fitting bonds (for example, through hooking).

The problems that occur when finely divided particle or fiber collectives are separated, fluidized and exposed in a time-controlled manner for the purpose of low-pressure sputter coating have not yet been solved or have only been solved insufficiently. Rotary drum systems or inclined rotary vessels having fins, which allow powder to be portioned, circulated or dropped (WO 2017/014304), have been published. Separation is only achieved with specific powders since only a small amount of mechanical energy is introduced into the material collective with these procedures and the methods primarily use gravity or a separation effect is based on the weight force, but depending on the particle size, the adhesive forces to be overcome are 100 to 100,000 times greater than the particle weight force. The same applies to fibers. The energy input into the collective and thus the deagglomeration can be increased by the input of impulse energy by means of impact, low-frequency or high-frequency vibration of the substance-receiving vessel (U.S. Pat. No. 6,355,146 B1). However, it is not possible to separate finely divided agglomerates, since the energy input into a collective is subject to damping, that is, force impacts are not efficiently introduced into agglomerates or the forces are not explicitly applied to the agglomerated composite, and therefore do not develop an effect that splits the agglomerates.

Furthermore, methods are known in which separation and fluidization takes place by introducing a gas flow having a low mass flow into a particle collective, optionally in combination with a vibrational excitation of a corresponding fluidized bed. (D. M. Baechle et al., Magnetron sputter deposition onto fluidized particle beds, Surface & Coatings Technology 221 (2013) 94-103 and B. Hua et al., Mater. Chem. Phys. 59 (1999) 130). The separation effect is low due to a low energy input. Also known are systems in which the material falls past the coating sources (CN 207592775). The problem here is that agglomerates are separated insufficiently either by the effect of gravity in free fall or only by impact and thus after passing through the coating zone. A disadvantage of all disclosed methods is that the separation of agglomerates is problematic, especially in the case of small particle sizes (<approx. 10 μm) and highly adhesive surfaces. In addition, the introduction or removal of powder or fiber material into or out of a vacuum system is not easily possible and controlled and continuous treatment is difficult.

### BRIEF SUMMARY OF THE INVENTION

Proceeding therefrom, it was the object of the present invention to provide a low-pressure coating system which makes possible an efficient separation of the particle or fiber collectives to be coated and a subsequent controlled, all-round and homogeneous coating.

This object is achieved by the low-pressure coating system having the features disclosed herein and the method for coating powders and fibers having the features disclosed herein. Also described are uses according to the invention and advantageous developments thereof.

### BRIEF DESCRIPTION OF THE DRAWINGS

FIG. 1 depicts a first variant according to the invention, in which the particles are separated from a particle collective (1) with the aid of a screen or perforation mask system.

FIG. 2 depicts a second variant according to the invention, in which the separation and fluidization of particles (1) takes place on a screen surface (10) positioned vertically or inclined.

FIG. 3 depicts a further embodiment of the present invention.

FIG. 4 shows a further device according to the invention, in which particle agglomerates (1a) of the particle collective (1), which is contained in a shell chamber (17), is separated from the screen fabric (13c) by means of impulse action, is driven through the screen meshes and then falls down (5a) through the plasma coating zone (18) in the form of separated particles (5).

FIG. 5 depicts how the substrate is raised again in the shell chamber as a result of the rotation (16b) and with the aid of fins (19) and the overall process is run through again.

### DETAILED DESCRIPTION OF THE INVENTION

According to the invention, a low-pressure coating system for coating powders or fibers by means of physical or chemical vapor deposition is provided, said system having the following units:
a coating source and a coating zone,
at least one deagglomeration unit having openings for separating the particle or fiber collectives, the at least one deagglomeration unit being arranged inside or above the coating zone and
at least one excitation unit connected to the at least one deagglomeration unit for transmitting impulses to the deagglomeration unit.

The deagglomeration unit is excited in the form of impulse transmission to said deagglomeration unit, which initiates a high-frequency oscillation or vibration of a thin screen mesh or narrow bars of a perforation mask, that is, the essential component of the deagglomeration unit. In this way, force impacts are effectively transmitted to a collective of particles or fibers, splitting them and driving separated material through the openings. At the same time, the openings, that is, the screen meshes or the mask perforations, have the function of holding back any non-cleavable agglomerates the size of which exceeds the opening size.

The coating source is preferably a PVD coating source, in particular a sputtering source or a CVD coating source.

The at least one deagglomeration unit is preferably selected from the group consisting of screens, perforation masks, lattices, nets or grids.

The openings of the at least one deagglomeration unit are preferably screen meshes, mask perforations, lattice or grid webs or slots.

The diameter of the openings is preferably in the range from 1 to 100 μm, preferably in the range from 2 to 50 μm and particularly preferably in the range from 5 to 20 μm. The distance between adjacent openings is preferably in the range from 1 to 100 μm, preferably in the range from 2 to 50 μm and particularly preferably in the range from 5 to 20 μm.

The openings of the deagglomeration unit are preferably separated from one another by bars or surrounded by edges.

It is preferred that the at least one deagglomeration unit is arranged perpendicularly to the direction of fall of the powder or the fibers. This allows the particles or fibers separated in the deagglomeration unit to be able to pass through the deagglomeration unit, for example, a screen or a perforation mask, and fall into the coating zone due to gravity in the coating system, in which coating zone the separated particles or fibers can then be coated.

An alternative preferred embodiment provides that the at least one deagglomeration unit is arranged vertically or inclined to the direction of fall of the powder or the fibers. In this case, the particles or the fibers then drift down along the surface of the deagglomeration unit in the coating system after passing through the openings of the deagglomeration unit. The deagglomeration unit faces the coating source so that the particles or fibers are coated while they drift along the surface.

At least two deagglomeration units are preferably arranged one below the other in the direction of fall of the particles or fibers, the diameter of the holes or openings of the deagglomeration units decreasing in the direction of fall.

Furthermore, it is preferred that the low-pressure coating system has a return device for returning the at least partially coated particles or fibers to the deagglomeration unit.

The low-pressure coating system preferably has a single-stage or multi-stage rotary valve, a single-stage or multi-stage double dump valve or a feed hopper having a sluice system for introducing and removing the particle or fiber collectives.

The at least one excitation unit is preferably selected from the group consisting of
excitation units for low-frequency vibrations, in particular in the range from 0.1 to 10 Hz,
ultrasonic excitation units, in particular for frequencies in the range from 20 to 100 kHz,
megasonic excitation units, in particular for frequencies in the 400 kHz to 5 MHz range, or
combinations thereof.

A preferred embodiment provides that the at least one deagglomeration unit is connected to a rotary drive unit, the deagglomeration unit preferably being connected to the rotary drive unit via a rotary axis.

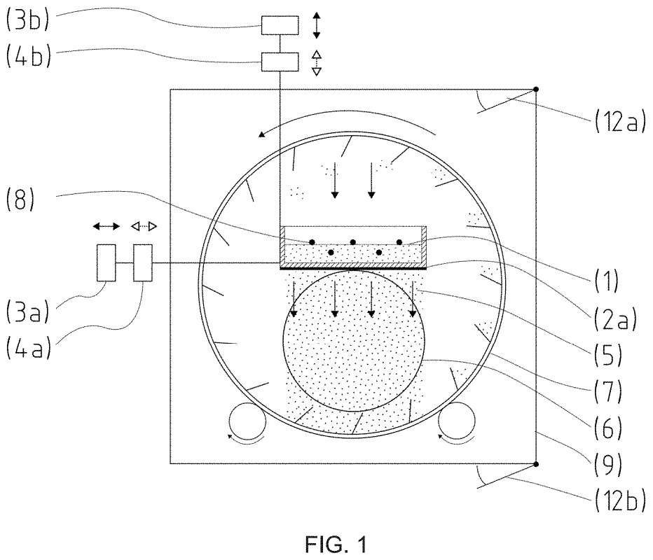

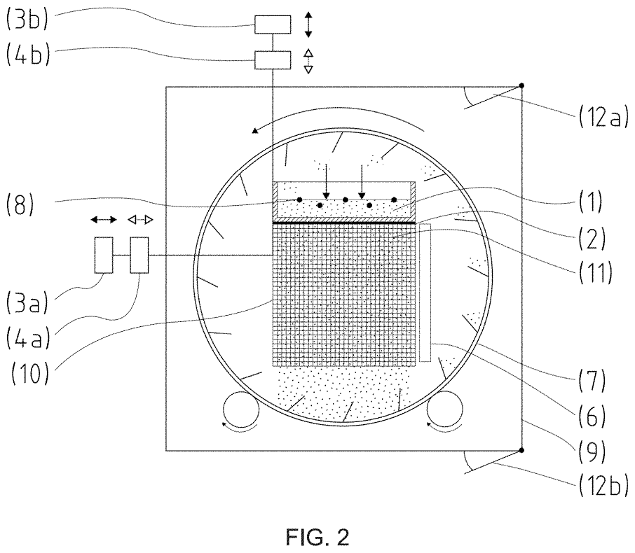

This preferred embodiment is based on a coating system having a rotary feedthrough according to the invention having an ultrasonic-transmitting axis of rotation and a screen drum mounted thereon. In the process, the rotation of the screen drum and the ultrasonic separation of powder are combined with one another with simultaneous continuous return, constant separation and coating inside the drum. A rotating return device as illustrated in FIG. 1 and FIG. 2 is thus not required. This solution therefore has structural and process engineering advantages over the embodiment of FIGS. 1 and 2. The need for a drive and rotary bearing for the return unit is thus eliminated. An improved powder return can further be assumed. After passing through the coating zone and being transported upwards from the lower spatial region of the shell chamber, powder material should be excellently detached from the drum surface or the fins as a consequence of drum vibration and gravity and fed back to the screen surface. In the return unit acc. FIGS. 1 and 2, only the effect of gravity is available for detaching any powder material adhering to the walls. For adhesive powders, there is a risk in the solution having a return unit that no material detachment and no return will be achieved.

According to the invention, there is also provided a method in which:
a) a powder or fibers to be coated are introduced into a low-pressure coating system having a coating source,
b) the particles or fibers to be coated are fed to a deagglomeration unit connected to an excitation unit such that impulses are transmitted to the deagglomeration unit,
c) force impacts are exerted on particle or fiber agglomerates by impulses, which cause the agglomerates to be separated and the separated particles or fibers to pass through the deagglomeration unit in the direction of fall, while remaining agglomerates are retained in the deagglomeration unit,
d) the particles or fibers are coated in a coating zone in the direction of fall below the at least one deagglomeration unit.

It is preferred that the at least one deagglomeration unit is arranged perpendicularly to the direction of fall of the powder or the fibers. An alternative preferred embodiment provides that the at least one deagglomeration unit is arranged vertically or inclined to the direction of fall of the powder or the fibers.

It is further preferred that the at least partially coated particles or fibers are returned to the deagglomeration unit by means of a return device. This enables continuous introduction into the coating zone. The substrate can thus be transferred to the coating zone again after coating has taken place, by which, for example, the thickness of the coating can be increased further.

It is preferred for the particle or fiber collectives to be introduced into the low-pressure coating system or removed from the low-pressure coating system via a single- or multi-stage rotary valve, a single- or multi-stage double dump valve or a feed hopper having a sluice system.

A plurality of deagglomeration units can be arranged one below the other by suitable cascading. It is preferred in this case for the openings of the individual deagglomeration units to become smaller in the direction of fall.

To increase the throughput of a single unit, the area of the separating elements in the deagglomeration unit, for example, the screen surface, can be increased, which is achieved by increasing the diameter and using a hopper that is subjected to vibration and/or ultrasound to reduce adhesion. Another possibility is a vertical, ring-shaped arrangement of a plurality of screens. Multi-stage screening processes can also be used. Sputtering targets can be designed as linear or ring sources with or without magnet support, both as planar and tubular cathodes. Construction as a hollow cylinder or hollow cone encompassing the fall distance is also possible. Instead of sputtering sources, plasma sources for PECVD can be used for surface modification, as can ion beam sources for ion beam etching or ion implantation.

A preferred embodiment provides that the deagglomeration, the separation and the particle or fiber throughput rate are increased by adding impulse-transmitting elements, such as balls. In none of the approaches known from the prior art is it possible for a comparably high energy input to overcome the adhesive forces to be achieved. In addition, according to the invention, particle agglomerates that could not be separated are held back in the deagglomeration unit. When using a screen, the non-separated agglomerates remain in the screen, while the separated particles or fibers pass through the screen and can be coated. In methods known from the prior art, on the other hand, there has hitherto been no possibility of fundamentally excluding undesirable agglomerates from the coating process or eliminating them in the process.

It is preferred for the at least one deagglomeration unit to be set into rotation by means of a rotary drive unit, the deagglomeration unit preferably being connected to the rotary drive unit via a rotary axis.

The subject according to the invention is to be explained in more detail with reference to the following figures, without wishing to restrict it to the specific embodiments shown here.

FIG. 1 depicts a first variant according to the invention, in which the particles are separated from a particle collective (1) with the aid of a screen or perforation mask system. The system can be a single screen (2a) or a single perforation mask or consist of a plurality of (2b . . . n) cascade-like screens or perforation masks aligned horizontally or at an angle to one another. An essential feature is that the mesh or hole size is smaller than the typical size of the agglomerates to be broken up. The minimum diameter can correspond to the average particle size present in the collective (d50 value of the powder) or to a specific fiber length. In the case of a cascade, the open screen/perforated area is successively reduced. In principle, the wire or bar diameter is designed to be as small as possible. The particles are separated by low-frequency (0.1-10 Hz) vibrations (3a, b) or by ultrasonic excitation (4a, b) (20-100 kHz) or by megasonic excitation (400 kHz-5 MHz) or combinations thereof. The excitation frequencies can be continuously varied to avoid or generate resonance effects, depending on the requirement. The excitation can be perpendicular (3b, 4b) to the screen surface or parallel thereto (3a, 4a); combinations are also possible. The ultrasonic or megasonic excitation can take place at the edge of the screen, through special contact points in the screen, or through an arrangement of sound conductors. The energy input can be regulated by varying the excitation (frequency, amplitude, pulse sequences). The separated particles (5) fall past a sputtering target (6) where said particles are exposed to coating species. The layer thickness is controlled by the fall distance, among other things. The process can be cycled by a return device (7). Additional mechanical energy can be introduced into the collective by impulse-transmitting bodies (small steel balls or similar) (8). The working conditions for PVD (low-pressure environment) require the components to be accommodated in a vacuum recipient (9). Furthermore, the coating system has two rotary valves (12a, 12b) via which the particle or fiber collectives can be introduced into the coating system or removed from the coating system.

FIG. 2 depicts a second variant according to the invention, in which the separation and fluidization of particles (1) takes place on a screen surface (10) positioned vertically or inclined. In connection with a suitable ultrasonic excitation of the element, it is possible to let the particle fluid drift down the surface of the element at a variable speed (11). At the same time, the surface faces the sputtering target (6), so that the coating takes place while the individual particles drift off on the screen surface. The layer thickness is controlled, among other things, by the drift speed of the particles. By varying the excitation (frequency, amplitude, pulse sequences) or introducing additional mechanical energy (hammer, balls), it is possible to adjust both the mass flow of the powder through the screen and the dwell time of the particles on the screen. One or more horizontally or inclined separation levels can be placed in front of the vertical or inclined screen.

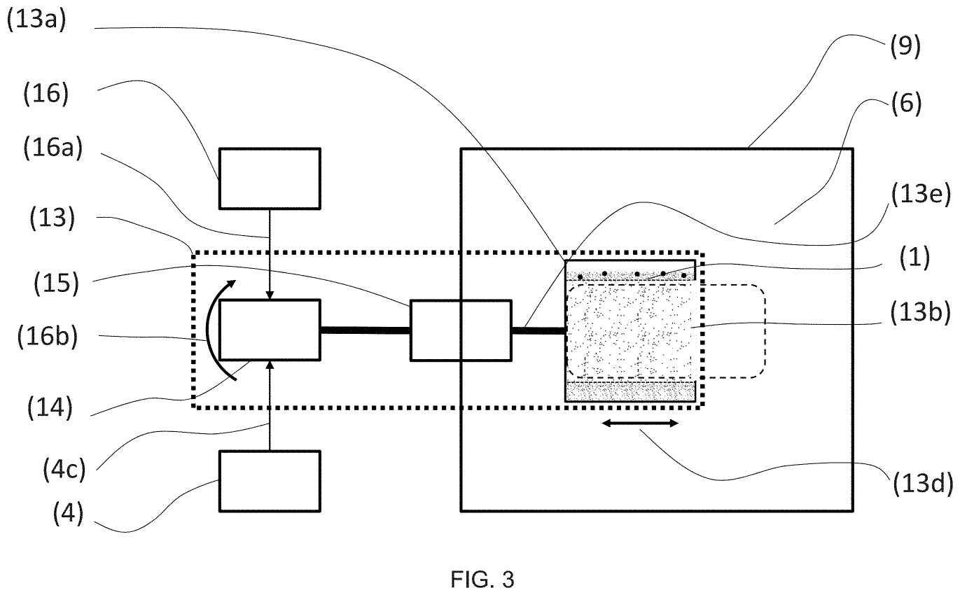

A further embodiment of the present invention is depicted in FIG. 3. A rotatable deagglomeration unit (13a) excited with ultrasound is depicted here in the form of a screen drum. The screen drum (13a) has an opening (13b) on one side. A screen fabric (13c) stretched over a frame is integrated into the screen drum (13a). The screen fabric is excited to vibrate (13d). The excitation of the screen fabric is initiated by an ultrasonic generator (4). After signal transmission (4c) to an ultrasonic converter (14), the ultrasonic waves are transferred from the normal pressure environment into the vacuum vessel via a rotary axis (13e) and a rotary feedthrough (15) into the interior of the vacuum chamber (9). The rotary feedthrough is also used to rotate (16b) the screen drum. The movement is caused by a motor (16) and transmission (16a) by means of, for example, a belt.

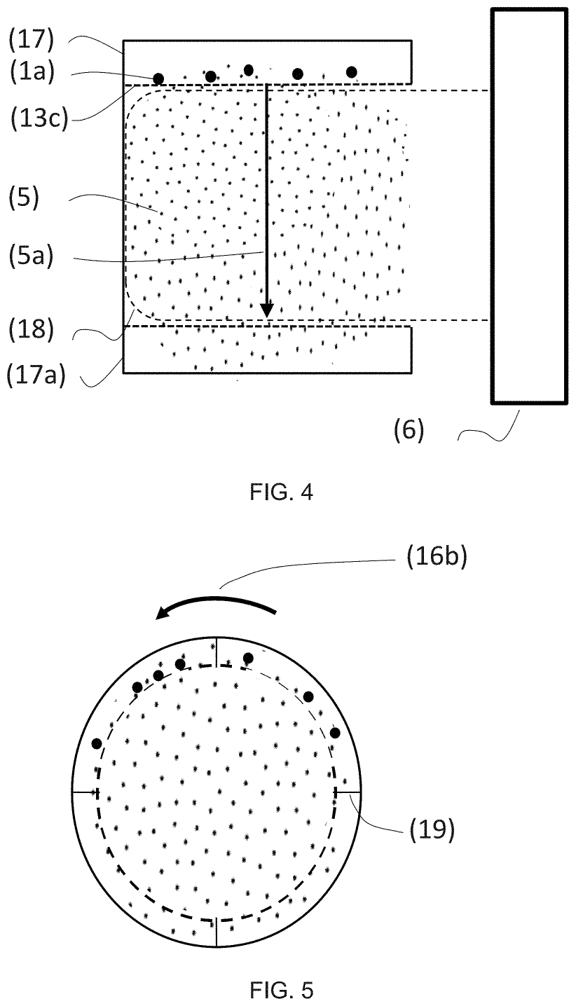

FIG. 4 shows a further device according to the invention, in which particle agglomerates (1a) of the particle collective (1), which is contained in a shell chamber (17), is separated from the screen fabric (13c) by means of impulse action, is driven through the screen meshes and then falls down (5a) through the plasma coating zone (18) in the form of separated particles (5). A plasma PVD source (6) releases coating material, that is, plasma-atomized target material, in this zone. After the particles have fallen through the plasma coating zone, said particles pass through the screen fabric again and into the lower spatial region of the shell chamber (17a). FIG. 5 depicts how the substrate is raised again in the shell chamber as a result of the rotation (16b) and with the aid of fins (19) and the overall process is run through again.

The following reference symbols are used in the figures:

FIGS. 1 and 2
1 Particle collective
2a Single screen/perforation mask
2b . . . n Plurality of screens or perforation masks aligned horizontally or at an angle to one another in a cascade-like manner
3a,b Low-frequency (0.1-10 Hz) vibrations
3a, 4a Excitation parallel to the screen surface
4a,b Ultrasonic excitation
4a,b Excitation perpendicular to the screen surface
5 Separated particles
6 Sputtering target
7 Return device
8 Impulse-transmitting body
9 Vacuum recipient
10 Screen surface positioned vertically or inclined
11 Drift surface
12a,b Rotary valves

FIGS. 3 to 5
13 Unit ultrasonically excited rotary screen
13a Screen drum
13b Opening of the screen drum/access for the plasma or the substrate
13c Screen fabric
13d Vibration movement
13e Rotary axis
4 Ultrasonic generator
4c Signal transmission
14 Ultrasonic converter
15 Rotary feedthrough
9 Vacuum chamber
16 Motor
16a Transmission
16b Rotational movement
1a Particle agglomerates
1 Particle collective
17 Shell chamber
17a Lower spatial region of the shell chamber
5 Separated particles
5a Particle direction of fall
6 Plasma coating zone
19 Sputtering target

1-24. (canceled)

25. A low-pressure coating system for coating particle or fiber collectives by physical or chemical vapor deposition comprising
a coating source and a coating zone,
at least one deagglomeration unit having openings for separating the particle or fiber collectives, wherein the at least one deagglomeration unit is arranged inside or above the coating zone, and
at least one excitation unit connected to the at least one deagglomeration unit for transmitting impulses to the deagglomeration unit.

26. The low-pressure coating system according to claim 25, wherein the coating source is a PVD coating source or a CVD coating source.

27. The low-pressure coating system according to claim 25, wherein the at least one deagglomeration unit is selected from the group consisting of screens, perforation masks, lattices, nets, and grids.

28. The low-pressure coating system according to claim 25, wherein the openings of the at least one deagglomeration unit are holes, meshes, or slits.

29. The low-pressure coating system according to claim 25, wherein the diameter of the openings is in the range from 1 to 100 μm and/or the distance between adjacent openings is in the range from 1 to 100 μm.

30. The low-pressure coating system according to claim 25, wherein the openings of the deagglomeration unit are separated by bars or surrounded by edges.

31. The low-pressure coating system according to claim 25, wherein the at least one deagglomeration unit is arranged perpendicularly to the direction of fall of the particles or the fibers.

32. The low-pressure coating system according to claim 25, wherein the at least one deagglomeration unit is arranged vertically or inclined to the direction of fall of the particles or the fibers.

33. The low-pressure coating system according to claim 25, wherein the least two deagglomeration units are arranged one below the other in the direction of fall of the particles or fibers, wherein the diameter of the holes or openings of the deagglomeration units decrease in the direction of fall.

34. The low-pressure coating system according to claim 25, wherein the low-pressure coating system includes a drum as a return device for returning the at least partially coated particles or fibers to the deagglomeration unit.

35. The low-pressure coating system according to claim 25, wherein the low-pressure coating system has a single-stage or multi-stage rotary valve, a single-stage or multi-stage double dump valve, or a feed hopper having a sluice system for introducing and removing the particle or fiber collectives.

36. The low-pressure coating system according to claim 25, wherein the at least one excitation unit is selected from the group consisting of
excitation units for low-frequency vibrations,
ultrasonic excitation units,
megasonic excitation units, and
combinations thereof.

37. The low-pressure coating system according to claim 25, wherein the at least one deagglomeration unit is connected to a rotary drive unit.

38. A method for coating particles or fibers by physical or chemical vapor deposition, in which
a) a particle or fiber collective to be coated is introduced into a low-pressure coating system having a coating source,
b) the particles or fibers to be coated are fed to a deagglomeration unit connected to an excitation unit so that impulses are transmitted to the deagglomeration unit,
c) force impacts are performed on particle or fiber agglomerates by the impulses, which cause the agglomerates to be separated and the separated particles or fibers to pass through the deagglomeration unit in the direction of fall, while remaining agglomerates are retained in the deagglomeration unit, and
d) the separated particles or fibers are coated in a coating zone in the direction of fall below the at least one deagglomeration unit.

39. The method according to claim 38, wherein the coating source is a PVD coating source or a CVD coating source.

40. The method according to claim 38, wherein the at least one deagglomeration unit is selected from the group consisting of screens, perforation masks, lattices, nets, and grids.

41. The method according to claim 38, wherein the at least one deagglomeration unit is arranged perpendicular to the direction of fall of the particles or fibers or arranged vertically or inclined to the direction of fall of the particles or fibers.

42. The method according to claim 38, wherein the at least partially coated particles or fibers are fed back to the at least one deagglomeration unit by a return device.

43. The method according to claim 38, wherein the particle or fiber collectives are introduced or removed in the low-pressure coating system via a single- or multi-stage rotary valve, a single- or multi-stage double dump valve, or a feed hopper having a sluice system.

44. The method according to claim 38, wherein the at least one excitation unit is selected from the group consisting of:
excitation units for low-frequency vibrations,
ultrasonic excitation units,
megasonic excitation units, and
combinations thereof.

45. The method according to claim 38, wherein impulse-transmitting elements are added in the deagglomeration unit in order to increase the deagglomeration, the separation and the particle throughput.

46. The method according to claim 38, wherein the at least one deagglomeration unit is set into rotation a rotary drive unit.

47. The method according to claim 38, wherein the low pressure coating system comprises:
a coating source and a coating zone,
at least one deagglomeration unit having openings for separating the particle or fiber collectives, wherein the at least one deagglomeration unit is arranged inside or above the coating zone, and
at least one excitation unit connected to the at least one deagglomeration unit for transmitting impulses to the deagglomeration unit.
